(19) United States
(12) Patent Application Publication
(10) Pub. No.: US 2016/0115797 A1
(43) Pub. Date: Apr. 28, 2016

(54) COATED ARTICLE AND METHOD FOR PRODUCING COATING

(71) Applicant: GENERAL ELECTRIC COMPANY, Schenectady, NY (US)

(72) Inventors: Eklavya CALLA, Bangalore (IN); Krishnamurthy ANAND, Bangalore (IN); Surinder Singh PABLA, Greer, SC (US)

(21) Appl. No.: 14/524,381

(22) Filed: Oct. 27, 2014

(51) Int. Cl. F01D 5/28; F01D 25/00; C23C 4/12; C23C 16/06; C23C 14/22; C23C 24/04; B32B 15/01; C23C 16/44

(52) U.S. Cl. CPC F01D 5/288; B32B 15/013; F01D 25/005; C23C 16/44; C23C 16/06; C23C 14/22; C23C 24/04; C23C 4/12

(57) ABSTRACT

A coated article and a method for producing a coating are disclosed. The method for producing a coating includes providing an iron-based alloy substrate, and depositing a protective coating over a surface of the iron-based alloy substrate. The protective coating includes a cobalt-chromium-based coating material having at least one anodic element distributed therein. The at least one anodic element being anodic to the iron-based alloy substrate. Another method for producing a coating includes providing an iron-based alloy substrate, depositing an underlayer including at least one anodic element over a surface of the iron-based alloy substrate, and depositing a top coat including a cobalt-chromium-based coating material over the underlayer. The at least one anodic element being anodic to the iron-based alloy substrate. The coated article includes a protective coating having at least one anodic element distributed therein deposited over a surface of an iron-based alloy substrate.

### FIELD OF THE INVENTION

The present invention is directed to a coated article and a method for producing a coating. More specifically, the present invention is directed to an anodically coated article and a method for producing an anodic coating.

### BACKGROUND OF THE INVENTION

Hot gas path components of gas turbines and aviation engines, particularly turbine blades, vanes, nozzles, seals and stationary shrouds, operate at elevated temperatures, often in excess of 2,000° F. These components are typically formed from iron-based alloy compositions, such as martensitic stainless steels.

Frequently, the hot gas path components are provided with protective coatings to reduce wear, erosion, corrosion, and/or degradation during operation. For example, to reduce or eliminate erosion and abrasion of gas and steam turbine components, particularly rear stage gas turbine compressor blades and vanes, an erosion-resistant or abrasion-resistant coating may be applied over the component. However, the erosion-resistant or abrasion-resistant coating may not provide protection against corrosion of the component.

Even in the absence of an erosion-resistant or abrasion-resistant coating, the martensitic stainless steels may experience corrosion due to material deposits formed on the surface of the component during operation (i.e., fouling). Additionally, the martensitic stainless steels may be anodic with respect to many of the erosion-resistant or abrasion-resistant coatings. When present, the galvanic incompatibility of the component and the coating increases the corrosion rate of the component.

Articles and methods having improvements in the process and/or the properties of the components formed would be desirable in the art.

### BRIEF DESCRIPTION OF THE INVENTION

In one embodiment, a method for producing a coating includes providing an iron-based alloy substrate, and depositing a protective coating over a surface of the iron-based alloy substrate, the protective coating comprising a cobalt-chromium-based coating material having at least one anodic element distributed therein. The at least one anodic element is anodic to the iron-based alloy substrate.

In another embodiment, a method for producing a coating includes providing an iron-based alloy substrate, depositing an underlayer over a surface of the iron-based alloy substrate, the underlayer comprising at least one anodic element, and depositing a top coat over the underlayer, the top coat comprising a cobalt-chromium-based coating material. The at least one anodic element is anodic to the iron-based alloy substrate.

In another embodiment, a coated article includes an iron-based alloy substrate, and a protective coating deposited over a surface of the iron-based alloy substrate, the protective coating comprising a cobalt-chromium-based coating material having at least one anodic element distributed therein. The at least one anodic element is anodic to the iron-based alloy substrate, and the protective coating including the at least one anodic element forms an anode with respect to the iron-based alloy substrate. The protective coating reduces galvanic corrosion of the iron-based alloy substrate.

Other features and advantages of the present invention will be apparent from the following more detailed description, taken in conjunction with the accompanying drawings which illustrate, by way of example, the principles of the invention.

### BRIEF DESCRIPTION OF THE DRAWINGS

FIG. 1 is a perspective view of a coated article.

FIG. 2 is a sectional view along lines 2-2 of FIG. 1 of the coated article, according to an embodiment of the disclosure.

FIG. 3 is an enhanced view of a coating deposited over the coated article of FIG. 2, according to an embodiment of the disclosure.

FIG. 4 is a sectional view of a coated article including an underlayer and a top coat, according to an embodiment of the disclosure.

Wherever possible, the same reference numbers will be used throughout the drawings to represent the same parts.

### DETAILED DESCRIPTION OF THE INVENTION

Provided are a coated article and a method for producing a coated article. Embodiments of the present disclosure, in comparison to methods and articles not using one or more of the features disclosed herein, decrease component corrosion, increase galvanic compatibility, maintain or substantially maintain wear-resistance of a coating, increase efficiency, increase an amount of time between inspection, increase operational lifetime, decrease maintenance costs, provide a single step corrosion and erosion protection coating process, permit wet compression in gas turbines, or a combination thereof.

When introducing elements of various embodiments of the present invention, the articles “a,” “an,” “the,” and “said” are intended to mean that there are one or more of the elements. The terms “comprising,” “including,” and “having” are intended to be inclusive and mean that there may be additional elements other than the listed elements.

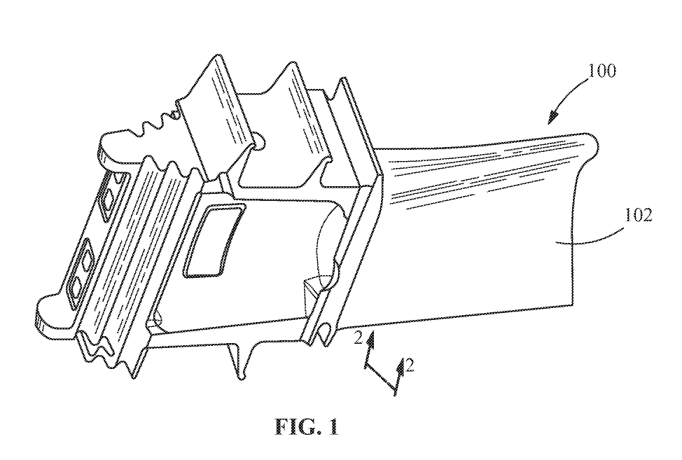

Referring to FIG. 1, a coated article 100 is depicted. The coated article 100 includes, but is not limited to, a turbine component, a hot gas path component, a rotating component, or a combination thereof. For example, in one embodiment, the coated article 100 includes a compressor bucket 102. In another embodiment, the coated article 100 includes a rear stage or last stage bucket. Other coated articles 100 may include a compressor vane, a centrifugal pump impeller, a pipeline, or a combination thereof. The term “bucket” as used herein is intended to be synonymous with the term “blade”.

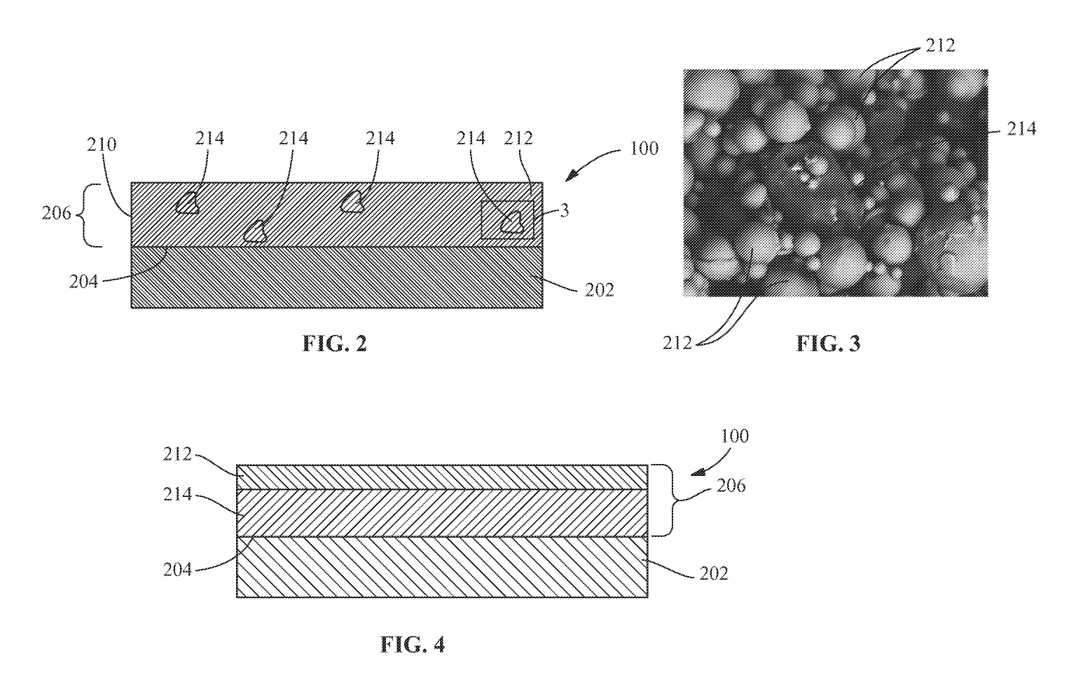

Referring to FIGS. 2-4, in one embodiment, the coated article 100 includes a substrate 202 defining a substrate surface 204, and a coating 206 over the substrate surface 204. The substrate 202 includes any substrate material having mechanical strength suitable for the operating conditions of the coated article 100. Suitable substrate materials include, but are not limited to, nickel-based alloys, iron-based alloys, ferrous materials, superalloys, or a combination thereof. As utilized herein, a nickel-based alloy is an alloy having an amount of nickel higher than any other element, and an iron-based alloy is an alloy having an amount of iron higher than any other element. For example, in another embodiment, the substrate 202 is formed from a martensitic stainless steel having a nominal composition, by weight percent, of about 15.5% chromium, about 6.3% nickel, about 1.5% copper, about 0.4% niobium, about 0.05% carbon, and the balance essentially iron and incidental impurities. Other suitable compositions for forming the substrate 202 include, but are not limited to, by weight percent, between about 11.0% and about 12.5% chromium, between about 2.0% and about 3.0% nickel, between about 1.5% and about 2.0% molybdenum, between about 0.5% and about 0.9% manganese, between about 0.25% and about 0.40% vanadium, between about 0.08% and about 0.15% carbon, between about 0.01% and about 0.05% nitrogen, up to about 0.35% silicon, and the balance essentially iron and incidental impurities; about 0.15% carbon, about 1.00% manganese, about 0.50% silicon, between about 11.5% and about 13.0% chromium, about 0.04% phosphorus, about 0.03% sulfur, and the balance essentially iron and incidental impurities; or a combination thereof.

The coating 206 includes any protective coating, such as, but not limited to, a wear coating, an erosion coating, a corrosion coating, or a combination thereof. As used herein, the term “protective coating” refers to a layer of material positioned over an article, such as the substrate 202, to reduce or eliminate erosion, abrasion, and/or corrosion of the article. In one embodiment, the coating 206 includes a coating material 212 and at least one anodic element 214. The coating material 212 includes any material suitable for reducing or eliminating erosion and/or abrasion of the substrate 202.

Suitable coating materials include wear-resistant coating materials, such as, but not limited to, cobalt-chromium-based (CoCr) alloys, WC-CoCr-based alloys, or a combination thereof. As utilized herein, a cobalt-chromium-based alloy is an alloy having a combined amount of cobalt and chromium higher than any other element. Additionally, as utilized herein, a tungsten carbide-cobalt-chromium-based alloy is an alloy having a combined amount of tungsten carbide, cobalt, and chromium higher than any other element. For example, one tungsten carbide-cobalt-chromium-based alloy includes, by weight, between about 80% and about 95% (e.g., 83% or 92%) tungsten carbide with a balance of either cobalt or cobalt-chromium, where the chromium is present at about 4%.

Compositions of the CoCr-based coatings include, for example, by weight percent, between about 27% and about 32% chromium, between about 4% and about 6% tungsten, between about 0.9% and about 1.4% carbon, up to about 3% nickel, up to about 3% iron, up to about 3% silicon, up to about 2% manganese, up to about 1.5% molybdenum, and the balance essentially cobalt and incidental impurities; between about 29.8% and about 30.2% chromium, between about 5.9% and about 6.1% tungsten, between about 1.05% and about 1.15% silicon, between about 1.4% and about 1.5% carbon, between about 0.5% and about 1.3% nickel, up to about 0.1% iron, up to about 0.1% manganese, between about 0.4% and about 0.6% molybdenum, and the balance essentially cobalt and incidental impurities; between about 28% and about 31% chromium, between about 8% and about 9% tungsten, between about 1.4% and about 1.85% carbon, between about 1% and about 2% silicon, between about 0.5% and about 1.5% manganese, up to about 3% nickel, up to about 2.5% iron, and a balance of cobalt and incidental impurities; about 29.5% chromium, about 8.5% tungsten, between about 1.4% and about 1.85% carbon, about 1.5% silicon, about 1% manganese, up to about 3% nickel, up to about 2.5% iron, and a balance of cobalt and incidental impurities; between about 31% and about 35% chromium, between about 16% and about 19% tungsten, between about 2.3% and about 2.6% carbon, between about 0.5% and about 1.5% silicon, between about 0.5% and about 1.5% manganese, up to about 2.5% nickel, up to about 2.5% iron, and a balance of cobalt and incidental impurities; about 33% chromium, about 17.5% tungsten, about 2.45% carbon, about 1% silicon, about 1% manganese, up to about 2.5% iron, up to about 2.5% nickel, and the balance essentially cobalt and incidental impurities; between about 29.8% and about 30.2% chromium, between about 6.9% and about 7.1% tungsten, between about 0.95% and about 1.05% silicon, between about 1.45% and about 1.55% carbon, between about 4.1% and about 4.9% nickel, up to about 0.1% iron, up to about 0.5% manganese, between about 1.9% and about 2.1% molybdenum, and the balance essentially cobalt and incidental impurities; or a combination thereof. The at least one anodic element 214 includes any element that is anodic with respect to the substrate 202. For example, elements which are anodic with respect to iron-based alloys include, but are not limited to, aluminum (Al), zinc (Zn), lithium (Li), or a combination thereof.

Referring to FIGS. 2-3, in one embodiment, the coating 206 includes the at least one anodic element 214 distributed throughout the coating material 212. In another embodiment, the at least one anodic element 214 is distributed throughout the coating material 212 in elemental form, as opposed to, for example, in oxide form. As illustrated in FIG. 3, in a further embodiment, the at least one anodic element 214 in elemental form includes particles having an angular, flattened, and/or spherical geometry, while the coating material 212 includes spherical particles. When the coating 206 is cold sprayed and/or thermally sprayed, and the at least one anodic element 214 is distributed throughout the coating material 212 in elemental form, the as-sprayed coating formed therefrom is devoid or substantially devoid of precipitates, such as, but not limited to, tungsten (W) and/or tungsten carbide (WC) precipitates. Subsequent heat treatment of the coating 206 forms the precipitates, which provide wear and/or erosion protection. In one embodiment, the heat treatment includes a multistep heat treatment including heating the coated article 100 to about 1100° C. and holding the coated article 100 at about 1100° C. for about 4 hours; cooling the coated article 100 to about 800° C. and holding the coated article 100 at about 800° C. for about 8 hours; and then cooling the coated article 100 to room temperature. Other heat treatments include, but are not limited to, single step heat treatment cycles including temperatures of, for example, about 450° C., about 800° C., and/or about 1100° C.

Forming the coating 206 including the at least one anodic element 214 distributed throughout the coating material 212 includes mixing/blending the at least one anodic element 214 with the coating material 212 prior to depositing the coating 206, and/or concurrently depositing the at least one anodic element 214 and the coating material 212. For example, in one embodiment, the forming of the coating 206 includes mixing the at least one anodic element 214 with the coating material 212 to form a coating mixture, then depositing the coating mixture over at least a portion of the substrate surface 204. The depositing of the coating mixture includes, but is not limited to, cold spraying, thermal spraying, or a combination thereof. In another embodiment, the forming of the coating 206 includes providing separate sources of the at least one anodic element 214 and the coating material 212, then concurrently depositing the at least one anodic element 214 and the coating material 212 over at least a portion of the substrate surface 204. The concurrent deposition includes, for example, vapor deposition, such as, but not limited to, chemical vapor deposition, electron beam vapor deposition, physical vapor deposition, or a combination thereof. During the concurrent deposition, the at least one anodic element 214 and the coating material 212 mix to form the coating 206 including the at least one anodic element 214 distributed throughout the coating material 212.

The coating 206 includes any suitable amount of the at least one anodic element 214 distributed throughout the coating material 212 to move an overall potential of the coating 206 from cathodic to anodic with respect to the substrate 202. Suitable amounts of the at least one anodic element 214 include, by volume percent, between about 1.5% and about 30%, between about 3% and about 30%, between about 5% and about 30%, between about 8% and about 30%, between about 3% and about 25%, between about 1.5% and about 15%, between about 1.5% and about 14%, between about 3% and about 14%, between about 10% and about 20%, between about 5% and about 14%, between about 1.5% and about 10%, between about 3% and about 10%, between about 8% and about 15%, between about 8% and about 14%, between about 10% and about 15%, between about 5% and about 10%, between about 10% and about 14%, between about 8% and about 12%, or any combination, sub-combination, range, or sub-range thereof. For example, in one embodiment, the coating material 212 includes, by weight, between about 0.1% and about 30% Al, between about 0.5% and about 30%, between about 1% and about 30% Al, between about 2% and about 30% Al, or any combination, sub-combination, range, or sub-range thereof. By moving the overall potential of the coating 206, the at least one anodic element 214 increases the galvanic compatibility of the coating 206, such that the coating 206 is sacrificed at the expense of the substrate 202. Thus, the increased galvanic compatibility decreases or eliminates corrosion (e.g., crevice formation, pitting) of the substrate 202, which increases an operational lifetime and/or reliability of the coated article 100.

Additionally, the at least one anodic element 214 increases the galvanic compatibility between the coating 206 and the substrate 202 without decreasing or substantially decreasing the wear-resistance of the coating material 212. As used herein, “without decreasing or substantially decreasing the wear-resistance of the coating material” means that the addition of the at least one anodic element 214 decreases the hardness value of the coating material 212 by less than about 15%, less than about 12%, less than about 10%, less than about 5%, between about 4% and about 11%, or any combination, sub-combination, range, or sub-range thereof. For example, mixing about 12% by volume aluminum with the CoCr-based coating material forms the coating 206 having about 2.5% by weight aluminum, and reduces the hardness value of the coating 206 from an HV_{0.3} of about 914 to an HV_{0.3} of about 871 (i.e., less than about 5%). In another example, mixing about 21% by volume aluminum with the CoCr-based coating material forms the coating 206 having about 5% by weight aluminum, and reduces the hardness value of the coating 206 from an HV_{0.3} of about 914 to an HV_{0.3} of about 821 (i.e., less than about 10%).

Referring to FIG. 4, in one embodiment, the coating 206 includes the at least one anodic element 214 deposited between the substrate surface 204 and the coating material 212. In another embodiment, the forming of the coating 206 includes depositing the at least one anodic element 214 over the substrate surface 204 to form an underlayer, then depositing the coating material 212 over the underlayer to form a top coat. In a further embodiment, the underlayer includes the at least one anodic element 214 deposited in elemental form. The at least one anodic element 214 includes any element that is anodic with respect to the substrate 202, such as, but not limited to, Al, Zn, Ni—Al, or a combination thereof. The at least one anodic element 214 and the coating material 212 may be deposited by any suitable deposition method disclosed herein. For example, depositing the at least one anodic element 214 may include cold spraying or thermal spraying, while depositing the coating material 212 may include cold spraying or high velocity oxygen fuel spraying (HVOF). The at least one anodic element 214 is deposited to any suitable thickness for increasing the galvanic compatibility between the coating 206 and the substrate 202. Suitable thicknesses of the underlayer include, but are not limited to, between about 1 and about 4 mils, between about 1.5 and about 3.5 mils, between about 2 and about 3 mils, or any combination, sub-combination, range, or sub-range thereof. Total thicknesses of the coating 206 (i.e., the underlayer and the top coat) include, but are not limited to, between about 2 and about 5 mils, between about 2.5 and about 4.5 mils, between about 3 and about 4 mils, or any combination, sub-combination, range, or sub-range thereof.

In one embodiment, the coating 206 is deposited over a leading edge of the compressor bucket 102, forming the coated article 100. In another embodiment, the coated article 100 is positioned within a low pressure and/or last stage section of a steam turbine. In a further embodiment, a power output from the gas turbine is augmented with wet compression, which includes injecting water into the compressor section of the gas turbine. During operation and/or wet compression, the coating 206 deposited over the leading edge of the compressor bucket 102 decreases or eliminates corrosion and/or water droplet erosion of the substrate 202.

While the invention has been described with reference to one or more embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A method for producing a coating, comprising:
providing an iron-based alloy substrate; and
depositing a protective coating over a surface of the iron-based alloy substrate, the protective coating comprising a cobalt-chromium-based coating material having at least one anodic element distributed therein;
wherein the at least one anodic element is anodic to the iron-based alloy substrate.

2. The method of claim 1, wherein the at least one anodic element is selected from the group consisting of elemental aluminum, elemental zinc, and combinations thereof.

3. The method of claim 1, further comprising combining the cobalt-chromium-based coating material and the at least one anodic element prior to the depositing of the protective coating.

4. The method of claim 3, wherein the depositing of the protective coating is selected from the group consisting of cold spraying, thermal spraying, and combinations thereof.

5. The method of claim 1, wherein the at least one anodic element is deposited separately from the cobalt-chromium-based coating material.

6. The method of claim 5, wherein the at least one anodic element is deposited by vapor deposition.

7. The method of claim 6, wherein the vapor deposition is selected from the group consisting of chemical vapor deposition, electron beam vapor deposition, physical vapor deposition, and combinations thereof.

8. The method of claim 1, further comprising depositing the protective coating to a thickness of between 3 and 4 mils.

9. The method of claim 1, wherein the at least one anodic element comprises particles having an angular flattened anodic geometry.

10. The method of claim 1, wherein a composition of the cobalt-chromium-based coating material comprises, in weight percent:
between about 27% and about 32% chromium;
between about 4% and about 6% tungsten;
between about 0.9% and about 1.4% carbon;
up to about 3% nickel;
up to about 3% iron;
up to about 3% silicon;
up to about 2% manganese;
up to about 1.5% molybdenum; and
a balance essentially cobalt and incidental impurities.

11. The method of claim 1, wherein the composition of the cobalt-chromium-based coating material comprises, in weight percent:
between about 29.8% and about 30.2% chromium;
between about 5.9% and about 6.1% tungsten;
between about 1.05% and about 1.15% silicon;
between about 1.4% and about 1.5% carbon;
between about 0.5% and about 1.3% nickel;
up to about 0.1% iron;
up to about 0.1% manganese;
between about 0.4% and about 0.6% molybdenum; and
a balance essentially cobalt and incidental impurities.

12. The method of claim 1, wherein the composition of the cobalt-chromium-based coating material comprises, in weight percent:
between about 29.8% and about 30.2% chromium;
between about 6.9% and about 7.1% tungsten;
between about 0.95% and about 1.05% silicon;
between about 1.45% and about 1.55% carbon;
between about 4.1% and about 4.9% nickel;
up to about 0.1% iron;
up to about 0.5% manganese;
between about 1.9% and about 2.1% molybdenum; and
a balance essentially cobalt and incidental impurities.

13. The method of claim 1, wherein a volume fraction of the at least on anodic element comprises between about 10% and about 30%.

14. The method of claim 1, wherein a volume fraction of the at least one anodic element comprises between about 1.5% and about 14%.

15. The method of claim 1, wherein the protective coating is substantially devoid of precipitates.

16. The method of claim 1, wherein the at least one anodic element in the protective coating decreases corrosion of the iron-based alloy substrate.

17. A method for producing a coating, comprising:
providing an iron-based alloy substrate;
depositing an underlayer over a surface of the iron-based alloy substrate, the underlayer comprising at least one anodic element; and
depositing a top coat over the underlayer, the top coat comprising a cobalt-chromium-based coating material;
wherein the at least one anodic element is anodic to the iron-based alloy substrate.

18. The method of claim 17, wherein the at least one anodic element is selected from the group consisting of aluminum, zinc, lithium, and combinations thereof.

19. The method of claim 17, further comprising depositing the underlayer to a thickness of between 2 and 3 mils.

20. A coated article, comprising:
an iron-based alloy substrate; and
a protective coating deposited over a surface of the iron-based alloy substrate, the protective coating comprising a cobalt-chromium-based coating material having at least one anodic element distributed therein;
wherein the at least one anodic element is anodic to the iron-based alloy substrate; and
wherein the protective coating including the at least one anodic element forms an anode with respect to the iron-based alloy substrate, the protective coating reducing galvanic corrosion of the iron-based alloy substrate.
